(19) United States
(12) Patent Application Publication
(10) Pub. No.: US 2025/0157794 A1
(43) Pub. Date: May 15, 2025

(54) SYSTEMS AND METHODS FOR REDUCING IRREGULARITIES WITHIN A PLASMA-BASED PROCESSING CHAMBER

(71) Applicant: Applied Materials, Inc., Santa Clara, CA (US)

(72) Inventors: Sheng Yi Wang, Tainan (TW); Fu Ting Chang, Tainan (TW)

(21) Appl. No.: 18/911,028

(22) Filed: Oct. 9, 2024

Related U.S. Application Data
(60) Provisional application No. 63/598,763, filed on Nov. 14, 2023.

(51) Int. Cl. H01J 37/32

(52) U.S. Cl. CPC H01J 37/32715; H01J 2237/20235

(57) ABSTRACT

A processing chamber for performing a plasma-based process onto a substrate is provided. The processing chamber includes a support structure that is configured to support a substrate within the processing chamber. The support structure is configured to displace in a vertical direction with respect to the processing chamber. The chamber further includes one or more lift pins configured to facilitate the transfer of a substrate to and from the support structure, which extend vertically through apertures of the support structure. Each lift pin of the one or more lift pins includes an inner shaft that includes a pin head and a lower pin portion, and an outer shaft that encompasses the inner shaft and includes an outer shaft head encompassing a portion of the inner shaft pin head, and a lower encompassing portion encompassing the lower pin portion. Both the inner shaft pin head and the outer shaft head can be formed from a material that is conductive.

### RELATED APPLICATIONS

This application is a continuation of U.S. Patent Application No. 63/598,763 filed Nov. 14, 2023, the entire contents of which are hereby incorporated by reference herein.

### TECHNICAL FIELD

Embodiments of the present disclosure relate generally to a substrate support assembly for reducing irregularities within a plasma-based processing chamber, and in particular to a substrate support assembly with reduced localized capacitance.

### BACKGROUND

Within a substrate manufacturing system, substrates can undergo various types of plasma-based processing in a specialized chamber, such as etching to remove material layers or deposition to add material layers. These chambers are highly controlled environments where parameters like temperature, pressure, and chemical concentration are precisely managed to achieve desired material properties.

Multiple lift pins are often used to receive and transfer a substrate to a dedicated substrate support assembly. The lift pins may be used during loading and unloading procedures, while the substrate support assembly may be used to ensure substrate stability and levelness during the processing. This minimizes the risk of defects or uneven material properties. Often, the lift pins and substrate support assembly are integrated. The material properties of each, together with their geometric and spatial arrangements can impact the efficacy of the plasma-based processed.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In some aspects, a processing chamber is provided. In some aspects, the processing chamber includes a support structure that is configured to support a substrate within the processing chamber, and that is configured to translate in a vertical direction with respect to the processing chamber, and one or more lift pins configured to facilitate a transfer of the substrate to and from the support structure, extending vertically through apertures of the support structure. In some aspects, each lift pin of the one or more lift pins includes an inner shaft comprising a pin head and a lower pin portion, and an outer shaft comprising an outer shaft head encompassing a portion of the inner shaft pin head, and a lower encompassing portion encompassing the lower pin portion. In some aspects, the outer shaft head includes a first conductive material.

In some aspects, a method for processing a substrate is provided. In some aspects, the method includes placing a substrate onto one or more pin heads of one or more lift pins extending vertically upwards through apertures of a support structure, vertically raising the support structure until the substrate is uniformly supported by the pin heads of the one or more lift pins and a supporting surface area of the support structure, performing a plasma-based process on the substrate, vertically lowering the support structure until the substrate is solely supported by the pin heads of the one or more lift pins, and removing the substrate from the one or more lift pins.

In some aspects, a system for processing a substrate is provided. In some aspects, the system includes a support structure that is configured to support a substrate within the processing chamber, and that is configured to translate in a vertical direction with respect to the processing chamber, and one or more lift pins configured to facilitate a transfer of the substrate to and from the support structure, extending vertically through apertures of the support structure. In some aspects, each lift pin of the one or more lift pins includes an inner shaft comprising a pin head and a lower pin portion, and an outer shaft comprising an outer shaft head encompassing a portion of the inner shaft pin head, and a lower encompassing portion encompassing the lower pin portion. In some aspects, the outer shaft head includes a first conductive material.

### BRIEF DESCRIPTION OF THE DRAWINGS

Aspects and implementations of the present disclosure will be understood more fully from the detailed description given below and from the accompanying drawings, which are intended to illustrate aspects and implementations by way of example and not limitation.

FIG. 1 illustrates a cut-away view of an example processing chamber of an example substrate manufacturing system, according to some embodiments of the present disclosure.

FIG. 2 illustrates a cut-away view of the example processing chamber of FIG. 1 during a plasma-based process, according to some embodiments of the present disclosure.

FIG. 3 illustrates an example lift pin of the processing chamber of FIG. 1, according to some embodiments of the present disclosure.

FIG. 4 illustrates an example portion of a processing chamber, according to some embodiments of the present disclosure.

FIG. 5 is a flow diagram of an example method of forming a monolithic substrate support device of a load lock in accordance with one embodiment of the present disclosure.

FIG. 6 illustrates an embodiment of a diagrammatic representation of a computing device associated with a substrate manufacturing system, in according to some embodiments of the present disclosure.

### DETAILED DESCRIPTION

Lift pins and the substrate support assembly within the processing chamber can be integrated both in form and functionality. For example, during plasma-based processes such as etching, deposition, cleaning, ashing, etc., plasma can be distributed within the chamber to enable precise processes. Within such processes, a susceptor is a commonly used component to enhances the effectiveness and speed of the plasma-based process on a substrate. Often, the substrate support assembly, including the lift pins, can perform or be a part of these susceptor functions.

A susceptor within a plasma-based processing chamber is typically made of a material that can absorb electromagnetic fields and is in contact with the substrate to be processed. The susceptor may transfer internally-generated, or plasma-based, energy to the substrate. For example, localized heating from the susceptor can improve the efficiency of plasma reactions, leading to faster etching or deposition rates and more uniform material properties. Other times, the susceptor can electromagnetically couple with the plasma, allowing enhanced energy transfer from the plasma to the substrate. To maintain the effectiveness of a susceptor as a tool within a plasma-based processing chamber, uniformity of heating and electro-magnetic properties within the substrate is crucial.

Susceptor performance and energy transfer is optimized when impedance within the susceptor is well-matched with the rest of the system, or when stray impedance is minimized within the susceptor. Matching the impedance ensures that the electromagnetic fields are efficiently absorbed by the susceptor, leading to more effective and uniform heating and, consequently, a more efficient plasma process. Impedance is often introduced through capacitive points, such as air gaps, or other insulative or dielectric locations, within the susceptor.

Managing impedance from a combination lift pins and substrate support assembly performing susceptor functionalities within a chamber presents challenges. For example, with respect to both lift pins and the support assembly, shielding is often used to prevent unwanted interactions with the plasma. Shielding may also protect a susceptor from potential damage due to high-energy particles in the plasma. Often, such shielding can be made of materials that are resistant to plasma erosion and can block electromagnetic interference (EMI).

However, the dielectric and insulative properties of the shielding used to protect the susceptor can introduce additional impedance into the system, which can impact the impedance matching. This added impedance can reduce the efficiency of energy transfer between the plasma and the susceptor, leading to less effective heating and potentially uneven material properties.

Thus, the embodiments described herein address the above, and other challenges, by introducing a modified substrate support assembly and lift pin design. The proposed design seeks to limit stray capacitance, and impedance, by eliminating air gaps, and reducing the use of dielectric or insulative shielding within the system.

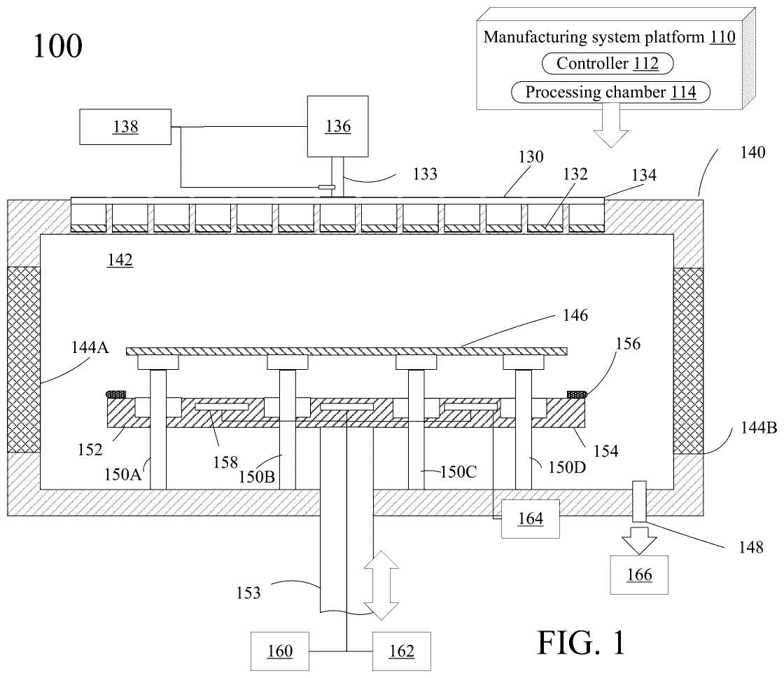

FIG. 1 illustrates a cut-away view of an example processing chamber of an example substrate manufacturing system, according to some embodiments of the present disclosure. The manufacturing system 100 (also referred to as “system” herein) includes a manufacturing system platform 110 that includes a controller 112 and a processing chamber 114.

In some embodiments, controller 112 may be associated with processing chamber 114. Controller 112 may monitor, adjust, and otherwise control the processes associated with manufacturing system 100, and associated components, such as processing chamber 114. In some embodiments, controller 112 and processing chamber 114 can be organized or combined in different configurations. For example, in some embodiments, controller 112 may be integral with processing chamber 114. In other embodiments, the controller may be on a server, or other computing device. In some embodiments, platform 110 may be a server, or other similar computing device.

In some embodiments, processing chamber 114 may perform plasma-based processes. The processing chamber may be coupled to a plasma source 136 via one or more gas delivery lines 133. The processing chamber 114 may be, for example, a plasma etch reactor, a deposition chamber, a cleaning chamber, an ashing chamber, etc., or any other type of processing chamber commonly used to effect plasma-based processes. The processing chamber may be suitable for an etching operation, a deposition operation, a chamber cleaning operation, a plasma treatment operation, or any other type of operation typical of a semiconductor manufacturing facility. In an embodiment, one or more substrates (e.g., wafers) 146 may be provided within the processing chamber. In an embodiment, the processing chamber may be maintained at a pressure suitable for the target operation. In a particular embodiment, the pressure may be between approximately 1 Torr and approximately 200 Torr.

The processing chamber 114 and/or plasma source 136 may be connected to the controller 112, which may control processing of the plasma source 136 and/or processing chamber 114 (e.g., by controlling set points, loading recipes, and so on). One or more flow sensors 138 may be connected to the gas delivery line(s) to detect gas flow characteristics.

In embodiments, the plasma source 136 is a remote plasma source (RPS) that generates plasma at a remote location and delivers the externally generated plasma to the processing chamber. Alternatively, the processing chamber may include an integrated plasma source (not shown) that can generate plasma within the processing chamber.

Processing chamber 114 includes a substrate support assembly 152, according to some embodiments. Substrate support assembly 152 includes a puck 154 (e.g., may include an electrostatic chuck (ESC)). The puck 154 may perform chucking operations, e.g., vacuum chucking, electrostatic chucking, etc. The puck 154 may further function as a chamber susceptor, in embodiments. Substrate support assembly 152 may further include base plate, cooling plate and/or insulator plate (not shown).

Processing chamber 114 includes chamber body 140 and lid 134 that enclose an interior volume 142. Chamber body 140 may be fabricated from aluminum, stainless steel, or other suitable material. Chamber body 140 generally includes sidewalls and a bottom. An outer liner (not shown in FIG. 1) may be disposed adjacent to the sidewalls, e.g., to protect chamber body 140. Such an outer liner may be fabricated and/or coated with a plasma or halogen-containing gas resistant material. Such an outer liner may be fabricated from or coated with aluminum oxide. Such an outer liner may be fabricated from or coated with yttria, yttrium alloy, oxides thereof, etc.

Exhaust port 148 may be defined in chamber body 140, and may couple interior volume 142 to a pump system 166. Pump system 166 may include one or more pumps, valves, lines, manifolds, tanks, etc., utilized to evacuate and regulate the pressure of interior volume 142.

Lid 134 may be supported on sidewall, or top, of chamber body 140. Lid 134 may be openable, allowing access to interior volume 142. Lid 134 may provide a seal for processing chamber 114 when closed. Plasma source 136 may be coupled to processing chamber 114 to provide process, cleaning, backing, flushing, etc., gases and/or plasmas to interior volume 142 through gas distribution assembly 130. Gas distribution assembly 130 may be integrated with lid 104.

Examples of processing gases that may be used in processing chamber 114 include halogen-containing gases, such as C2F6, SF6, SiCl4, HBr, NF3, CF4, CHF3, CH2F3, Cl2 and SiF4. Other reactive gases may include O2 or N2O. Non-reactive gases may be used for flushing or as carrier gases, such as N2, He, Ar, etc. Gas distribution assembly 130 (e.g., showerhead) may include multiple inlets 132 on the downstream surface of gas distribution assembly 130. Inlets 132 may direct gas flow to the surface of substrate 146. In some embodiments, gas distribution assembly may include a nozzle (not pictured) extended through a hole in lid 134. A seal may be made between the nozzle and lid 134. Gas distribution assembly 130 may be fabricated and/or coated by a ceramic material, such as silicon carbide, yttrium oxide, etc., to provide resistance to processing conditions of processing chamber 114.

Substrate support assembly 152 is disposed in interior volume 142 of processing chamber 114 below gas distribution assembly 130. Substrate support assembly 152 may hold a substrate 144 during processing. An inner liner (not shown) may be coated on the periphery of substrate support assembly. The inner liner may share features (e.g., materials of manufacture, function, etc.) with outer liner 116.

Substrate support assembly 152 may include supporting pedestal 153, insulator plate, base plate, cooling plate, lift pins 150A-D, and puck 154. Puck 154 may include electrodes 158 for providing one or more functions. Electrodes 158 may include chucking electrodes (e.g., for securing substrate 146 to an upper surface of puck 154), heating electrodes, RF electrodes for plasma control, etc.

Protective ring 156 may be disposed over a portion of puck 154 at an outer perimeter of puck 154. Puck 154 may be coated with a protective layer (not shown in FIG. 1). In embodiments, the protective layer may be a ceramic such as Y2O3 (yttria or yttrium oxide), Y₄Al₂O₉ (YAM), Al₂O₃ (alumina), Y₃Al₅O₁₂ (YAG), YAlO₃ (YAP), quartz, SiC (silicon carbide), Si₃N₄ (silicon nitride), Sialon, AlN (aluminum nitride), AlON (aluminum oxynitride), TiO₂ (titania), ZrO₂ (zirconia), TiC (titanium carbide), ZrC (zirconium carbide), TiN (titanium nitride), TiCN (titanium carbon nitride), Y₂O₃ stabilized ZrO₂ (YSZ), and so on. The protective layer may be a ceramic composite such as YAG distributed in an alumina matrix, a yttria-zirconia solid solution, a silicon carbide-silicon nitride solid solution, or the like. The protective layer may be sapphire or MgAlON.

Puck 154 may further include multiple gas passages such as grooves, mesas, and other features that may be formed in an upper surface of puck 154. Gas passages may be fluidly coupled to a gas source 164. Gas from gas source 164 may be utilized as a heat transfer or backside gas. Multiple gas sources may be utilized (not shown). Gas passages may provide a gas flow path for a backside gas such as He via holes drilled in puck 154. Backside gas may be provided at a controlled pressure into gas passages to enhance heat transfer between puck 154 and substrate 144.

Puck 154 may include one or more clamping electrodes. The clamping electrodes may be controlled by chucking power source 160.

In some embodiments, the puck 154 may provide some susceptor functionalities. For example, clamping electrodes may further couple to one or more RF power sources 162 through a matching circuit for maintaining a plasma formed from process and/or other gases within processing chamber 114. The RF power sources may be capable of producing an RF signal having a frequency from about 50 kilohertz (kHz) to about 3 gigahertz (GHz) and a power of up to about 40,000 Watts. Heating electrodes of puck 154 may be coupled to heater power source 162 (RF power source 162 may also provide energy to heating).

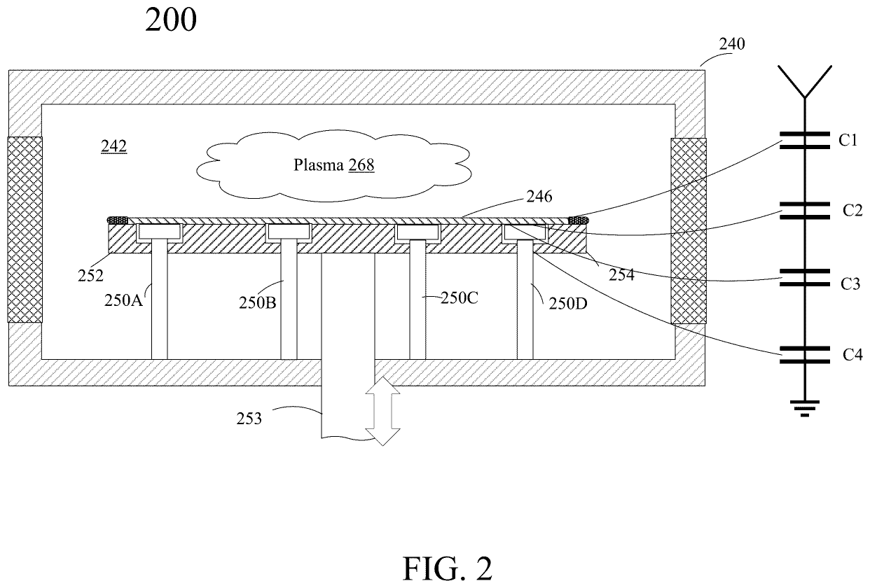

Controller 112 may control one or more parameters and/or set points of the plasma source 136 and/or processing chamber 114. System controller 112 can be and/or include a computing device such as a personal computer, a server computer, a programmable logic controller (PLC), a microcontroller, and so on. System controller 112 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 112 can include, or platform 110 may include, a data storage device (e.g., one or more disk drives and/or solid state drives), a main memory, a static memory, a network interface, and/or other components. System controller 112 can execute instructions to perform any one or more of the methodologies and/or embodiments described herein. The instructions can be stored on a computer readable storage medium, which can include the main memory, static memory, secondary storage and/or processing device (during execution of the instructions). In embodiments, execution of the instructions by system controller 176 causes system controller to raise and lower the support assembly 152 and pedestal, as will be further discussed with respect to FIG. 2. In embodiments, system controller 112 may receive measurements from one or more flow sensors indicating a flow parameter (e.g., pressure, flow rate, etc.), and may adjust one or more properties or settings (e.g., such as a plasma power) of plasma source 136 responsive to the measured radical concentration. System controller 112 can also be configured to permit entry and display of data, operating commands, and the like by a human operator.

In embodiments, data captured from sensors such as sensors 138, may reflect a variety of data associated with processing chamber 114. For example, in embodiments, sensors within the processing chamber may capture pressure, temperature, gas flow rates, etc., or any other data commonly captured within a plasma-based processing chamber.

In some embodiments, when a substrate is transferred into the processing chamber e.g., via doors 144A or doors 144B, the substrate will be received onto lift pins 150A-D (as is seen in the configuration of FIG. 1). After the substrate has been received, the support assembly 152 and pedestal 153 may raise to remove the meet the substrate (as will be seen in the configuration of FIG. 2). A process may then be effected. In some embodiments, after the process has completed, the support assembly 152 may lower and the lift pins may lift the substrate off of the lift pins. This lifting may facilitate removal from the chamber. In embodiments, the support assembly 152 and puck 154 may match the lift pins at a height with respect to the chamber.

FIG. 2 illustrates a cut-away view of the example processing chamber of FIG. 1 during a plasma-based process, according to some embodiments of the present disclosure.

In some embodiments, the processing chamber 200 may correspond, or be similar to processing chamber 114, as seen and described in FIG. 1, and incorporate and augment at least the embodiments described therein. Some components found in chamber 114 of FIG. 1, e.g., the gas distribution system, flow inlets, exhaust system, etc. have been removed from the example processing chamber 200 seen in FIG. 2. This is not meant to limit the disclosure or remove their presence from example processing chamber 200. These components have only been excluded in an effort to simply the figure and disclosure with respect to other components. One should appreciate that processing chamber may still include these, and other features, not shown in FIG. 2. Despite this, in embodiments, some of the components of chamber 200, as seen in FIG. 2, e.g., the chamber body 240, interior volume 242, puck 254, substrate 246, and lift pins 250A-D, etc. may still correspond, or be similar to the components of chamber 114 as seen and described in FIG. 1, and incorporate and augment at least the embodiments described therein.

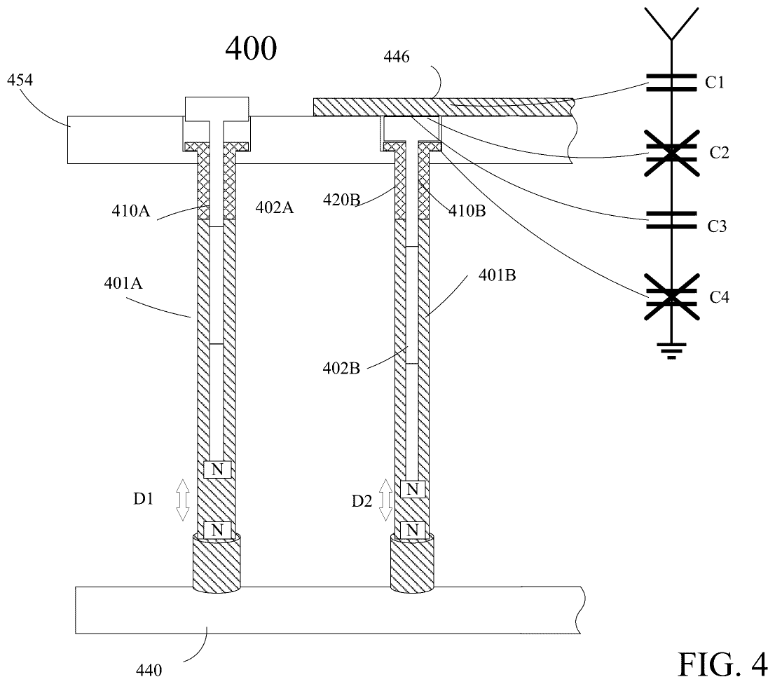

For example, within FIG. 2, a lid, gas distribution system, and flow inlets (which are not shown, for simplicities sake) may facilitate a plasma-based process including plasma 268 within the interior volume 242 of chamber body 240 of the chamber 200. Within the chamber, substrate support assembly 252 and puck 254 may be raised to meet the height of lift pins 250A-D. As will be further described in FIG. 4, in embodiments, the substrate 246 may rest equally on both the puck 254 and the lift pins 250A-D.

In embodiments, puck 254 and lift pins 250A-D may serve dual functions within chamber 200. For example, puck 254 may first provide a stable platform for holding the substrate, and may also acts as a susceptor to enhance the effectiveness of the plasma process. In embodiments, puck 254 may be a passive, or an active, susceptor. For example, in some embodiments, puck 254 may include electrodes (not shown in FIG. 2) that perform heating, or electrical functions. In embodiments, puck 254 may be constructed from a material that is both thermally and electrically conductive, such as aluminum, graphite, etc. As discussed with respect to FIG. 1, puck 254 may be coated with a protective layer of a material such as silicon carbide, to shield against corrosion, contamination etc.

In embodiments, when radio frequency (RF) power is applied to the chamber, puck 254 may further act as a susceptor, and couple with the electromagnetic field generated by the plasma. Such a coupling may allow the puck to absorb energy from the plasma and distribute energy uniformly across the substrate. In embodiments, this energy absorption can lead to localized heating, which can enhance the effectiveness of the plasma-based process of the chamber (e.g., chemical vapor deposition (CVD), atomic level deposition (ALD), plasma etching, etc. as was discussed above). Thus, uniform heat distribution is crucial to ensure the plasma-based process occurs evenly across the entire substrate, for quality and consistency.

In additional embodiments, where puck 254 is an active susceptor. Puck 254 may be electrically biased through internal electrodes to control the ion energy distribution hitting the substrate. By applying a voltage to the puck, puck 254 may attract ions from the plasma towards the substrate with a determined kinetic energy, allowing for more precise control over etching rates, deposition characteristics, etc.

In embodiments, the capacitance, and impedance, between components associated with the lift pins 250A-D and puck 254 may greatly influence the efficacy of the plasma-based processes. In particular, irregular capacitive locations within the puck may introduce impedance into the system.

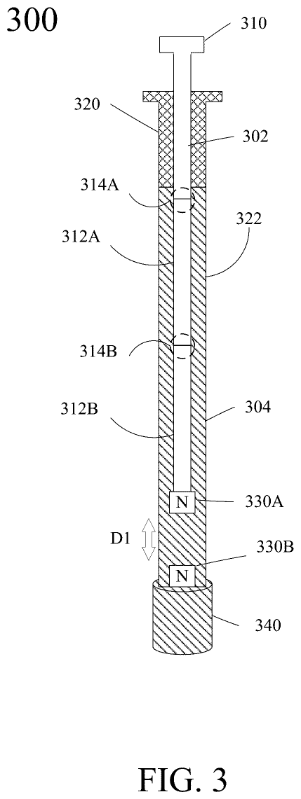

As discussed, in embodiments, lift pins 250A-D may be employed to elevate the substrate e.g., during loading, unloading, cooling, etc. As seen in FIG. 2, these lift pins can introduce geometric and electrical irregularities in the susceptor characteristics of the puck 254. These irregularities can particularly affect impedance within the puck. For example, the lift pins 250A-D may be made of any combinations of conductive and nonconductive materials. As will be further discussed in FIG. 3, conductive materials like stainless steel, aluminum, etc. may be used. Non-conductive materials like ceramics or polymers, etc. may be used together with the conductive materials. These materials may introduce different electrical and thermal properties compared to the material of the puck 254. Furthermore, any airgaps between the geometries or spaces between the lift pins and the puck may further act as insulative materials, introducing capacitance and impedance into the system. Some of these local capacitances will be described with respect to capacitances C1-C4, as seen in FIG. 2.

In embodiments where RF power is applied to generate plasma 268 (in alternate embodiments plasma may have been generated elsewhere), the electromagnetic field may interact with all above-mentioned conductive and capacitive elements in the chamber. Diverse materials introduced through the lift pins can create localized variations or non-uniformities in the electromagnetic field, leading to non-uniform impedance distribution across the puck 254. These irregularities can result in uneven power coupling to the plasma, which may affect the uniformity and quality of the plasma-based processes.

For example, when the lift pins are retracted, as in the embodiment seen in FIG. 2, the lift pins may recede into recess within a top surface of the puck 254. Irregularities within the fittings between the lift pins and puck can introduce stray capacitance, and stray impedance into the system.

For example, in embodiments where the lift pins are misaligned, maligned, or introduce air gaps between the substrate support assembly or the substrate, these factors can create localized temperature or energy field variations within the chamber. This can alter the thermal and energy uniformity and, consequently, create irregularities in the fields, processes, and finished substrate.

In embodiments, both air gaps and diverse materials may introduce irregular capacitance, and therefore impedance, into the system. Such added capacitance can alter the resonant frequency of the substrate support assembly 252, making it more challenging to maintain stable and uniform plasma conditions. The stray capacitance can lead to unpredictable changes in the overall electrical behavior of the plasma processing system.

As seen in FIG. 2, some of the introduced capacitances of the system can be characterized, and reduced. Other capacitances will be inherent. For example, capacitances C1-C4 can be included within the system. Capacitance C1, can originate from the substrate itself, and may be inherent to the system, based on the substrate composition (e.g., glass, or silicone, etc.). Capacitance C2, may originate from any air gap between the top of the lift pin and the substrate. This capacitance may be reduced or eliminated. In embodiments, this capacitance can be removed by ensuring the top portion of the pin is precisely fitted to uniformly interface with the substrate above. In cases where the lift pin top has been anodized, a capacitance C3, may originate due to this layer of anodization on the lift pin. Similarly, if the lift pin has an outer layer elsewhere, e.g., any shielding, anodization, ceramic protective layers, etc. the outer layer contacting the puck 254 at other locations may introduce a capacitance C4. This capacitance can be reduced, or eliminated. These irregularities, and methods to reduce them, will be further described with respect to FIGS. 3-4.

Thus, the material composition, spacing, fitting, geometry, etc. of the lift pins 250A-D and puck 254 may influence capacitance, impedance, energy coupling, and the efficacy of the processing chamber.

FIG. 3 illustrates an example lift pin of the processing chamber of FIG. 1, according to some embodiments of the present disclosure.

In some embodiments, the lift pin 300 can include an inner shaft 302, and an outer shaft 304. In embodiments, the inner shaft may be axially displaceable with respect to the outer shaft. In embodiments, the inner shaft may include a pin head 310, and pin shaft segments 312A and 312B that extend axially through the lift pin. The outer shaft may include base 340, segment 322 and outer shaft head 320.

In embodiments, the inner shaft 302 may be displaced upwards by a pair of similarly polarized permanent magnets 330A-B placed at the base of the lift pin. In some embodiments, the permanent magnets may introduce a spacing of D1 between terminal ends of the inner shaft 302, and the outer shaft 304. In embodiments, this distance D1 may be reduced when downward pressure, or weight is placed on the pin head 310 of the inner shaft 302.

In some embodiments, magnets 330A-B may be any kind of repelling magnets, including electromagnets, superconductive magnets, Halbach arrays, hybrid magnets, etc., or any other type of repelling magnets commonly used within a substrate manufacturing system.

In embodiments, the inner shaft 302 may be divided into segments. In embodiments, three pin shaft segments 310, 312A, and 312B (including the pin head) may be included. The pin shaft segments may interface at junctions 314A and 314B of the inner shaft. In alternate embodiments, more than three pin shaft segments may be used. In alternate embodiments, the permanent magnets 330A-B may be placed at any of the alternate interface locations, including those of configurations not seen in FIG. 3 (e.g., when the inner shaft is divided into 4, 5, or any number of segments).

In embodiments, the segments of the shaft pins may serve to limit heat transfer throughout the inner shaft, and lift pin in general. When the pin head 310 contacts the substrate, and the outer shaft head 320 contacts the support assembly, heat may be transferred to the lift pin. Thus, more than three segments may be included, to limit the heat transfer. This limit on heat transfer, may server to protect components within the pin 300. This may include protecting the permanent magnets from heat damage.

In a similar manner, in embodiments, the outer shaft 304 may be divided into longitudinal segments. In embodiments, the outer shaft 304 may be segmented into an outer shaft head 320, a lower segment 322, and a base 340.

In some embodiments, the inner shaft may include similarly polarized permanent magnets 330A-B, that provide a separating force on the inner shaft. In embodiments, the force provided by permanent magnets 330A-B may propel the inner shaft 302 upwards a distance D1.

In embodiments, the permanent magnets may be placed at the bottom of the lift pin, to limit damage from heat entering the pin at the pin head 310. In embodiments, the permanent magnets may be placed at junction 314B, or junction 314A, and the segments may be lengthened to properly place the permanent magnets away from damage caused by heat.

In some embodiments, any segments of either the inner, or outer, shaft may be made of varying materials. For instance, in embodiments, the outer shaft may be made from two different materials. The outer shaft head 320 may be made of a conductive material e.g., aluminum, intended to minimize, or cancel electrical resistance or impedance between the outer shaft head 320 and the puck (as will be seen in FIG. 4).

Often, within plasma-based processing chambers, ceramic material may be used for shielding components and controlling the electrical characteristics of the chamber. Ceramic is resistant and protective to the types of processes often transpiring within the chamber. Ceramic material typically has a high dielectric constant, which means a significant amount of electrical charge and also a significant level of impedance may be introduced to the system. As previously discussed, this impedance can impact the controlled generation and sustainment of plasma within the chamber, affecting parameters like plasma density, uniformity, and energy distribution.

Replacing the dielectric ceramic at the outer shaft head with a conductive material such as aluminum may significantly decreases the impedance at that point. This can result is a more efficient coupling of the electrical power into the plasma, which effectively leads to higher plasma densities and higher uniformity within the plasma field.

Moreover, reduced impedance at the contact point may also mean that less energy is lost in the form of heat or electromagnetic radiation, thus improving the overall energy efficiency of the plasma-based processing chamber.

Thus, in embodiments, the lift pin may combine multiple compositional materials. In embodiments, the outer shaft head 320 of the pin may be aluminum, or another similarly conductive material, while the lower portions of outer shaft 304 may be ceramic, or polymer, or any other heat resistant material, commonly used within plasma-based processing chambers.

In some embodiments, any of the above portions or elements may include a plasma-resistant coating, such as a ceramic coating or any other kind of plasma-resistant coating, to enhance durability in the plasma environment.

One of ordinary skill in the art, having the benefit of this disclosure, will appreciate that numerous materials, configurations, and segment amounts and lengths, for both the inner and outer shafts of pin 300 exist, and that the configurations and materials described above are exemplary representations of a lift pin, and of the possible configurations associated with a lift pin of the system.

FIG. 4 illustrates an example portion of a processing chamber, according to some embodiments of the present disclosure.

In some embodiments, the components seen within portion 400 of FIG. 4, such as the puck 454, substrate 446, lift pins 401A-B, etc., and chamber body 440, may correspond, or be similar to puck 154, 254, substrate 146, 246, any subset of lift pins 150A-D, 250A-D, 300, etc., and chamber body 140 and 240, as seen and described in FIGS. 1-3, and incorporate and augment at least the embodiments described therein.

As seen within FIG. 4, the example portion 400 may including a portion of a puck 454 (and the corresponding substrate support assembly) and two lift pins 401A-B that stretch through a portion of puck 454. The base of lift pins 401A-B may rest on a portion of the chamber body 440. A substrate 446 (or the portion seen), may rest on lift pin 401B, but not on pin 401A.

As seen in FIG. 4, the weight of substrate 446 may be sufficient to compress the inner shaft 402B of pin 401B such that the distance between the two magnets in the base of pin 401B is decreased to be D2. D1 may be less than the uncompressed distance, D1, as seen in pin 401A.

As seen in FIG. 4, the pin head 410B is forced downward by the weight of the substrate. While this occurs, the repulsive force from the magnets at the base may become greater, such that the pin head may be pressed against the bottom face of substrate 446. In embodiments, the top surface of the pin head may uniformly interact with the underside of the substrate. Thus, the repulsive force from the magnets may help to reduce or eliminate the airgap between the pin head 410B and the substrate 446. This feature may help to remove inductive resistance from capacitance C2 from the system.

Furthermore, within FIG. 4, a slight gap between pin head 410B and the surrounding portion of the puck 454 may be seen. This is within FIG. 4, only to help the reader and for the sake of pictorial simplicity. In practice, these air gaps may be eliminated as much as feasible, such that pin head 410B, and outer shaft head 420B are firmly pressed against the surrounding bodies of the puck 454 and substrate 446. Thus, air gaps between the puck 454, substrate 446, and compressed lift pin 401B may be limited.

As discussed with respect to FIG. 3, in embodiments, both pin head 410B and the outer shaft heads 420B of pin 401B may be made of a type of conductive material e.g., aluminum, such that the impedance from the capacitance C4 at this contact point is removed from the system.

Similarly, the impedance introduced by capacitance C4 by the shielding material and outer shaft head 420B may be reduced or eliminated by its material composition.

Pin 401A may include similar components and materials as described with respect to pin 401B. However, pin 401A may illustrate a lift pin in an uncompressed state, such that repelling magnets in the base provide a lift distance D1 to the inner shaft, and pin head 410A. In embodiments, pin 401A may react similarly to a vertical weight, and compress in a similar manner as seen with respect to pin 401B.

In embodiments, all lift pins associated with a puck (e.g., puck 454) may operate in tandem, and the mismatched configuration of pins 401A and 401B may only be seen as exemplary.

As was seen and discussed within FIGS. 1-2, a puck may include four lift pins that extend through apertures within the puck to interface with a substrate. One of ordinary skill in the art, having the benefit of this disclosure, will appreciate that the puck and pins are three dimensional, and that numerous three-dimensional spatial layouts, configurations, resting heights, aperture diameters, amounts, etc. for the pins, the puck, and the substrate support assembly at large, exist. One of ordinary skill in the art, having the benefit of this disclosure, will appreciate that the layouts and configurations as seen in FIG. 4, as well as analogous elements in FIGS. 1-3 are an exemplary representation of a puck, support assembly, and lift pins, associated with the system, and that other variations or embodiments are possible.

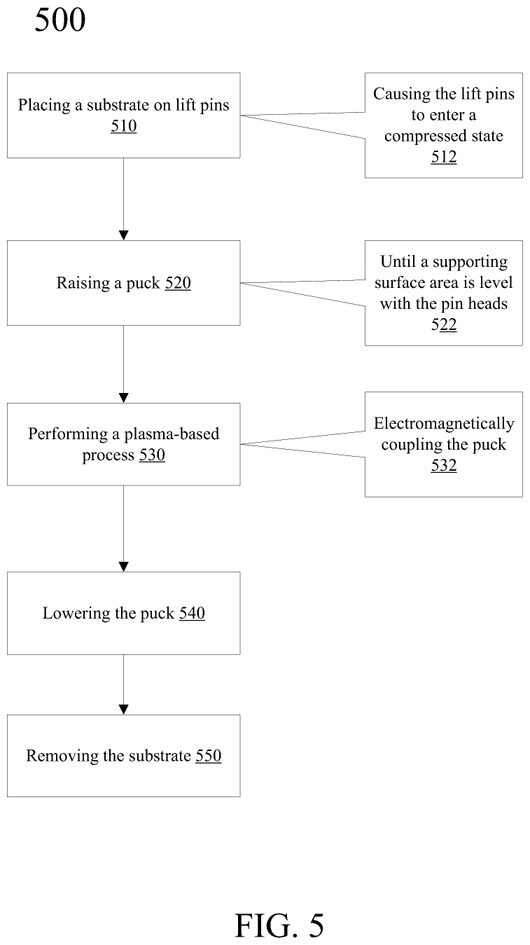

FIG. 5 is a flow diagram of an example method of forming a monolithic substrate support device of a load lock in accordance with one embodiment of the present disclosure.

FIG. 5 illustrates a method 500 that may be performed by a manufacturing device that may include hardware, software, or a combination of both. The manufacturing device may make use of a processing chamber, one or more controllers, and substrate support devices including one or more lift pins and a puck.

At block 510, method 500 may include placing a substrate on lift pins. In some embodiments, block 510 may further include placing a substrate onto one or more pin heads of one or more lift pins extending vertically upwards through apertures of a puck.

At block 512, method 500 may include causing the lift pins to enter a compressed state. In some embodiments, block 512 may further include causing the lift pins to enter a compressed state wherein the longitudinal distance that the pin head of the inner shaft extends past the outer shaft head of the outer shaft is reduced.

At block 520, method 500 may include raising a puck. In some embodiments, block 520 may further include vertically raising the puck until the substrate is uniformly supported by the pin heads of the one or more lift pins and a supporting surface area of the puck.

At block 522, method 500 may include raising a puck until a supporting surface area is level with the pin heads. In some embodiments, block 522 may further include vertically raising the puck until the supporting surface area is level with the pin heads of the lift pins when the lift pins are in the compressed state.

At block 530, method 500 may include performing a plasma-based process. In some embodiments, block 530 may further include performing a plasma-based process on the substrate.

At block 532, method 500 may include electromagnetically coupling the puck. In some embodiments, block 532 may further include electromagnetically coupling the puck and the one or more lift pins with a plasma.

At block 540, method 500 may include lowering the puck. In some embodiments, block 540 may further include vertically lowering the puck until the substrate is solely supported by the pin heads of the one or more lift pins.

At block 550, method 500 may include removing the substrate. In some embodiments, block 550 may further include removing the substrate from the one or more lift pins.

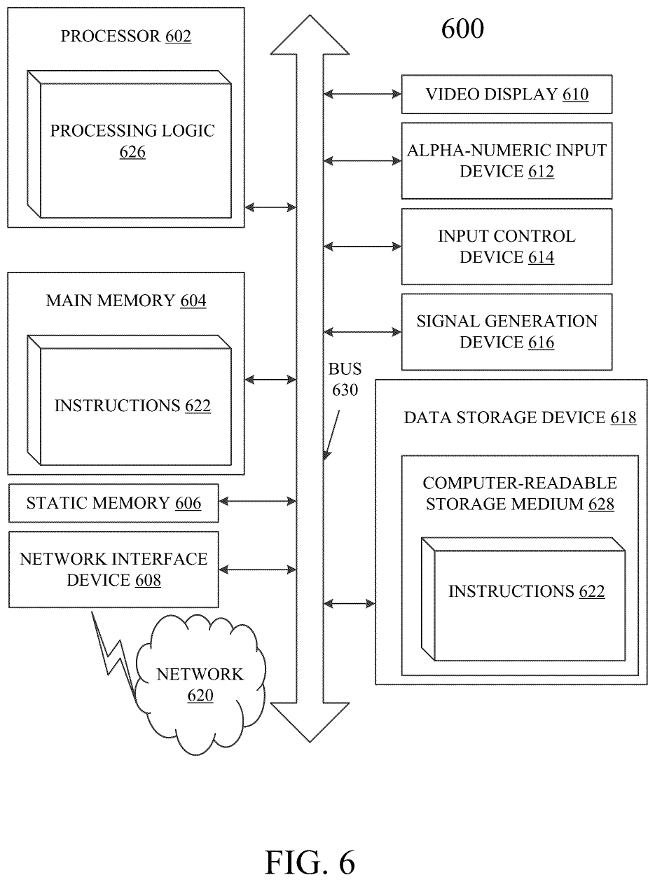

FIG. 6 illustrates an embodiment of a diagrammatic representation of a computing device associated with a substrate manufacturing system, in according to some embodiments of the present disclosure.

FIG. 6 illustrates a processing device 600 that may be a part of any computing device associated with any of the above described figures, or any combination thereof. Example processing device 600 may be connected to other processing devices in a LAN, an intranet, an extranet, and/or the Internet. The processing device 600 may be a personal computer (PC), a set-top box (STB), a server, a network router, switch or bridge, or any device capable of executing a set of instructions (sequential or otherwise) that specify actions to be taken by that device. Further, while only a single example processing device is illustrated, the term “processing device” shall also be taken to include any collection of processing devices (e.g., computers) that individually or jointly execute a set (or multiple sets) of instructions to perform any one or more of the methods discussed herein.

Example processing device 600 may include a processor 602 (e.g., a CPU), a main memory 604 (e.g., read-only memory (ROM), flash memory, dynamic random access memory (DRAM) such as synchronous DRAM (SDRAM), etc.), a static memory 606 (e.g., flash memory, static random access memory (SRAM), etc.), and a secondary memory (e.g., a data storage device 618), which may communicate with each other via a bus 630.

Processor 602 represents one or more general-purpose processing devices such as a microprocessor, central processing unit, or the like. More particularly, processor 602 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 602 may also be one or more special-purpose processing devices such as an application specific integrated circuit (ASIC), a field programmable gate array (FPGA), a digital signal processor (DSP), network processor, or the like. In accordance with one or more aspects of the present disclosure, processor 602 may be configured to execute instructions (e.g. instructions 622 may include a computing subsystem or controller as seen at least in FIG. 1).

Example processing device 600 may further comprise a network interface device 608, which may be communicatively coupled to a network 620. Example processing device 600 may further comprise a video display 610 (e.g., a liquid crystal display (LCD), a touch screen, or a cathode ray tube (CRT)), an alphanumeric input device 612 (e.g., a keyboard), an input control device 614 (e.g., a cursor control device, a touch-screen control device, a mouse), and a signal generation device 616 (e.g., an acoustic speaker).

Data storage device 618 may include a computer-readable storage medium (or, more specifically, a non-transitory computer-readable storage medium) 628 on which is stored one or more sets of executable instructions 622. In accordance with one or more aspects of the present disclosure, executable instructions 622 may comprise executable instructions.

Executable instructions 622 may also reside, completely or at least partially, within main memory 604 and/or within processor 602 during execution thereof by example processing device 600, main memory 604 and processor 602 also constituting computer-readable storage media. Executable instructions 622 may further be transmitted or received over a network via network interface device 608.

While the computer-readable storage medium 628 is shown in FIG. 6 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

It should be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

The embodiments of methods, hardware, software, firmware or code set forth above may be implemented via instructions or code stored on a machine-accessible, machine readable, computer accessible, or computer readable medium which are executable by a processing element. “Memory” includes any mechanism that provides (i.e., stores and/or transmits) information in a form readable by a machine, such as a computer or electronic system. For example, “memory” includes random-access memory (RAM), such as static RAM (SRAM) or dynamic RAM (DRAM); ROM; magnetic or optical storage medium; flash memory devices; electrical storage devices; optical storage devices; acoustical storage devices, and any type of tangible machine-readable medium suitable for storing or transmitting electronic instructions or information in a form readable by a machine (e.g., a computer).

Reference throughout this specification to “one embodiment” or “an embodiment” means that a particular feature, structure, or characteristic described in connection with the embodiment is included in at least one embodiment of the disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In the foregoing specification, a detailed description has been given with reference to specific exemplary embodiments. It will, however, be evident that various modifications and changes may be made thereto without departing from the broader spirit and scope of the disclosure as set forth in the appended claims. The specification and drawings are, accordingly, to be regarded in an illustrative sense rather than a restrictive sense. Furthermore, the foregoing use of embodiment, embodiment, and/or other exemplarily language does not necessarily refer to the same embodiment or the same example, but may refer to different and distinct embodiments, as well as potentially the same embodiment.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such. Also, the terms “first,” “second,” “third,” “fourth,” etc. as used herein are meant as labels to distinguish among different elements and may not necessarily have an ordinal meaning according to their numerical designation.

A digital computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a digital computing environment. The essential elements of a digital computer a central processing unit for performing or executing instructions and one or more memory devices for storing instructions and digital data. The central processing unit and the memory can be supplemented by, or incorporated in, special purpose logic circuitry or quantum simulators. Generally, a digital computer will also include, or be operatively coupled to receive digital data from or transfer digital data to, or both, one or more mass storage devices for storing digital data, e.g., magnetic, magneto-optical disks, optical disks, or systems suitable for storing information. However, a digital computer need not have such devices.

Digital computer-readable media suitable for storing digital computer program instructions and digital data include all forms of non-volatile digital memory, media and memory devices, including by way of example semiconductor memory devices, e.g., EPROM, EEPROM, and flash memory devices; magnetic disks, e.g., internal hard disks or removable disks; magneto-optical disks; CD-ROM and DVD-ROM disks.

Control of the various systems described in this specification, or portions of them, can be implemented in a digital computer program product that includes instructions that are stored on one or more non-transitory machine-readable storage media, and that are executable on one or more digital processing devices. The systems described in this specification, or portions of them, can each be implemented as an apparatus, method, or system that may include one or more digital processing devices and memory to store executable instructions to perform the operations described in this specification.

While this specification contains many specific embodiment details, these should not be construed as limitations on the scope of what may be claimed, but rather as descriptions of features that may be specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

What is claimed is:

1. A processing chamber, comprising:
a support structure that is configured to support a substrate within the processing chamber, and that is configured to translate in a vertical direction with respect to the processing chamber; and
one or more lift pins configured to facilitate a transfer of the substrate to and from the support structure, extending vertically through apertures of the support structure, wherein each lift pin of the one or more lift pins comprises:
an inner shaft comprising a pin head and a lower pin portion; and
an outer shaft comprising an outer shaft head encompassing a portion of the inner shaft pin head, and a lower encompassing portion encompassing the lower pin portion;
wherein the outer shaft head comprises a first conductive material.

2. The processing chamber of claim 1, wherein the processing chamber is configured to perform a plasma-based process on the substrate, the plasma-based process comprising at least one of a deposition process, an etching process, an ashing process, or a cleaning process.

3. The processing chamber of claim 1, wherein the support structure and one or more pin heads of the one or more lift pins are configured to function as a susceptor in a plasma-based process within the processing chamber.

4. The processing chamber of claim 1, wherein the support structure comprises one or more electrodes configured to perform at least one of chucking, heating, or providing radio frequency (RF) energy.

5. The processing chamber of claim 1, wherein the one or more pin heads of the one or more lift pins each comprise a second conductive material.

6. The processing chamber of claim 1, wherein each lift pin of the one or more lift pins further comprises:
a first repelling magnet coupled to a base of the outer shaft longitudinally opposite the outer shaft head; and
a second repelling magnet coupled to a terminal end of the inner shaft longitudinally opposite the pin head;
wherein the first and second repelling magnets provide a force which causes the pin head of the inner shaft to protrude a first distance from outer shaft head of the outer shaft in a longitudinal direction.

7. The processing chamber of claim 6, wherein a weight of the substrate resting on the pin head of a lift pin causes the lift pin to compress such that the first distance the pin head of the inner shaft protrudes from the outer shaft head is reduced to a second distance.

8. The processing chamber of claim 1, wherein the substrate is placed on the one or more lift pins and the support structure is vertically translated such that a top surface of the support structure is at the same vertical height of top surfaces of the one or more lift pins, wherein the top surface of the support structure and the top surfaces of the one or more lift pins uniformly contact an underside of a supported substrate.

9. The processing chamber of claim 1, wherein one or more lift pins comprise a first surface that uniformly contacts a second surface of the support structure.

10. The processing chamber of claim 1, wherein the lower encompassing portion of the outer shaft can be the same or different from the first material.

11. The processing chamber of claim 1, wherein each lift pin of the one or more lift pins comprises an inner shaft that comprises one or more longitudinal segments.

12. The processing chamber of claim 11, wherein the one or more longitudinal segments can be any kinds of materials including ceramic, metal, or plastic.

13. A method for processing a substrate comprising:
placing a substrate onto one or more pin heads of one or more lift pins extending vertically upwards through apertures of a support structure;
vertically raising the support structure until the substrate is uniformly supported by the pin heads of the one or more lift pins and a supporting surface area of the support structure;
performing a plasma-based process on the substrate;
vertically lowering the support structure until the substrate is solely supported by the pin heads of the one or more lift pins; and
removing the substrate from the one or more lift pins.

14. The method of claim 13, wherein each lift pin of the one or more lift pins comprises an inner shaft and an outer shaft, wherein the inner shaft comprises the pin head, wherein in an uncompressed state of the lift pin the pin head extends a first longitudinal distance past an outer shaft head of the outer shaft.

15. The method of claim 14, wherein the inner shaft comprises one or more longitudinal segments.

16. The method of claim 14, wherein the outer shaft comprises a first repelling magnet coupled to a base of the outer shaft that is opposite the outer shaft head, wherein the inner shaft comprises a second repelling magnet coupled to a terminal end of the inner shaft that is opposite the pin head, wherein the first and second repelling magnets provide a force to raise the inner shaft such that the pin head extends the first longitudinal distance past an outer shaft head of the outer shaft.

17. The method of claim 16, wherein placing a substrate onto one or more pin heads of the one or more lift pins causes the lift pins to enter a compressed state wherein the first longitudinal distance is reduced to a second longitudinal distance, and an overall longitudinal length of each lift pin is reduced.

18. The method of claim 17, wherein vertically raising the support structure until the substrate is uniformly supported comprises vertically raising the support structure until the supporting surface area is level with the pin heads of the lift pins when the lift pins are in the compressed state.

19. The method of claim 17, wherein performing a plasma-based process on the substrate comprises electromagnetically coupling the support structure and the one or more lift pins with a plasma.

20. A system for processing a substrate comprising:
a support structure that is configured to support a substrate within the processing chamber, and that is configured to translate in a vertical direction with respect to the processing chamber; and
one or more lift pins configured to facilitate a transfer of the substrate to and from the support structure, extending vertically through apertures of the support structure, wherein each lift pin of the one or more lift pins comprises:
an inner shaft comprising a pin head and a lower pin portion; and
an outer shaft comprising an outer shaft head encompassing a portion of the inner shaft pin head, and a lower encompassing portion encompassing the lower pin portion;
wherein the outer shaft head comprises a first conductive material.
